(19) United States
(12) Patent Application Publication
(10) Pub. No.: US 2014/0216954 A1
(43) Pub. Date: Aug. 7, 2014

(54) CASE FOR ELECTRICAL DEVICE AND METHOD OF USING SAME

(71) Applicant: Belkin International, Inc., Playa Vista, CA (US)

(72) Inventors: Henry Law, Orange, CA (US); Barry P. Sween, Santa Monica, CA (US); Xin Fu, Guangdong (CN); Jeong Lee, Buena Park, CA (US); Oliver Duncan Seil, Pasadena, CA (US); Ernesto Quinteros, Los Angeles, CA (US); Yin Chen, San Gabriel, CA (US)

(73) Assignee: Belkin International, Inc., Playa Vista, CA (US)

(21) Appl. No.: 14/244,779

(22) Filed: Apr. 3, 2014

Related U.S. Application Data
(63) Continuation-in-part of application No. 14/184,408, filed on Feb. 19, 2014.
Application No. 14/184,408 is a continuation of application No. 13/568,040, filed on Aug. 6, 2012, now Pat. No. 8,684,174.
Application No. 13/568,040 is a continuation of application No. 12/782,592, filed on May 18, 2010, now Pat. No. 8,235,208.
Application No. 12/782,592 is a continuation of application No. 11/810,823, filed on Jun. 6, 2007, now Pat. No. 7,735,644.
(60) Provisional application No. 61/808,203, filed on Apr. 3, 2013.

(51) Int. Cl. A45C 11/00; H05K 5/02

(52) U.S. Cl. CPC A45C 11/00; H05K 5/0226; A45C 2011/001; A45C 2011/002; A45C 2011/003
USPC 206/45.23; 29/428

(57) ABSTRACT

Some embodiments include a case for an electrical device. The case includes a support assembly configured to be removably coupled to the electrical device. The case also includes a first portion coupled to at least a portion of the support assembly. The case further includes a second portion coupled to the first portion at a first hinge. The case also includes a third portion hingedly coupled to the second portion. The case further includes a fourth portion hingedly coupled to the third portion. The fourth portion includes a hand support assembly at an inner surface of the fourth portion. The hand support assembly includes a perimeter frame, an inner frame, and a channel between the perimeter frame and the inner frame. Other embodiments are provided.

### CROSS-REFERENCE TO RELATED APPLICATIONS

This patent application is a non-provisional application of U.S. Provisional Patent Application No. 61/808,203, filed Apr. 3, 2013. This patent application is also a continuation-in-part patent application of U.S. patent application Ser. No. 14/184,408, filed Feb. 19, 2014, which is a continuation patent application of U.S. patent application Ser. No. 13/568,040, filed Aug. 6, 2012, now U.S. Pat. No. 8,684,174, which is a continuation patent application of U.S. patent application Ser. No. 12/782,592, filed May 18, 2010, now U.S. Pat. No. 8,235,208, which is a continuation patent application of U.S. patent application Ser. No. 11/810,823, filed Jun. 6, 2007, now U.S. Pat. No. 7,735,644.

U.S. Provisional Patent Application No. 61/808,203, U.S. patent application Ser. No. 14/184,408, U.S. patent application Ser. No. 13/568,040, U.S. patent application Ser. No. 12/782,592, and U.S. patent application Ser. No. 11/810,823 are incorporated herein by reference in their entirety.

### TECHNICAL FIELD

This invention relates generally to cases for electrical devices, and relates more particularly to cases that are configured for supporting and using electrical devices when held by a user.

### BACKGROUND

Advancing technology has made portable electrical devices increasingly popular and has given such electrical devices an ever-increasing array of capabilities. Some electrical devices, such as digital music and video players, cellular phones, personal digital assistants, handheld digital computers, tablet computers, and the like, include the capability to display images or videos. Most portable electrical devices include display or touch screens and/or control mechanisms. It would be convenient for the user of such electrical devices if a case allowed easy viewing of the display screen and operation of the electrical device in both handheld and hands-free configurations, without requiring the user to remove it from the case.

Accordingly, a need or potential for benefit exists for a case for an electrical device that protects the electrical device, allows it to be securely held for operating and view, and, in another configuration, allows it to maintain a hands-free operating and viewing position.

### BRIEF DESCRIPTION OF THE DRAWINGS

The invention will be better understood from a reading of the following detailed description of examples of embodiments, taken in conjunction with the accompanying figures in the drawings in which:

FIG. 1 illustrates a bottom, side isometric view of a case in a first embodiment of an open configuration and enclosing an electrical device, according to a first embodiment of the case;

FIG. 2 illustrates a top, front, side isometric view of the case of FIG. 1 in a second embodiment of an open configuration, according to the first embodiment of the case;

FIG. 3 illustrates a top, back, side isometric view of the case of FIG. 1 in a third embodiment of an open configuration, according to the first embodiment of the case;

FIG. 4 illustrates a side view of the case of FIG. 1 in a closed configuration and enclosing the electrical device of FIG. 1, according to the first embodiment of the case;

FIG. 5 illustrates another top, front, side isometric view of the case of FIG. 1 in a fourth embodiment of an open configuration and enclosing the electrical device of FIG. 1, according to the first embodiment of the case;

FIG. 6 illustrates a cross-sectional view along line I-I of FIG. 2 of the case of FIG. 1 in the second embodiment of an open configuration, according to the first embodiment of the case;

FIG. 7 illustrates a side view of a case in an open configuration and enclosing an electrical device, according to a second embodiment of the case;

FIG. 8 illustrates a top, front, side isometric view of a case in a first embodiment of an open configuration and enclosing an electrical device, according to a third embodiment of the case;

FIG. 9 illustrates a top, back, side isometric view of the case of FIG. 8 in a second embodiment of an open configuration, according to the third embodiment of the case;

FIG. 10 illustrates bottom, side isometric view of the case of FIG. 8 in a third embodiment of an open configuration, according to the third embodiment of the case;

FIG. 11 illustrates a flow chart for an embodiment of a method of using a case with an electrical device;

FIG. 12 illustrates a top view of a case in an open, unfolded configuration with a tablet computing device removed, according to another embodiment;

FIG. 13 illustrates a top view of the case of FIG. 12 in an open, unfolded configuration and holding the tablet computing device;

FIG. 14 illustrates a cross-sectional, side elevational view of the case of FIG. 12 in an open, unfolded configuration, where the cross-sectional view is taken along cross-sectional line 14-14 in FIG. 12;

FIG. 15 illustrates a side elevational view of the case of FIG. 12 in a viewing configuration with a tablet computing device;

FIG. 16 illustrates a top view of the case of FIG. 12 in a closed configuration, showing the outer side of the front cover;

FIG. 17 illustrates a bottom view of the case of FIG. 12 in a closed configuration, showing the outer side of the back cover;

FIG. 18 illustrates a bottom view of the case of FIG. 12 in a tablet configuration, showing the inner side of the front cover; and

FIG. 19 illustrates a flow chart for an embodiment of a method for providing a case for an electrical device, according to another embodiment.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Furthermore, the terms “include,” and “have,” and any variations thereof, are intended to cover a non-exclusive inclusion, such that a process, method, system, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical, physical, mechanical, or other manner. The term “on,” as used herein, is defined as on, at, or otherwise adjacent to or next to or over.

### DESCRIPTION OF EXAMPLES OF EMBODIMENTS

Some embodiments include a case for an electrical device. The case includes a support assembly configured to be removably coupled to the electrical device. The case also includes a first portion coupled to at least a portion of the support assembly. The case further includes a second portion coupled to the first portion at a first hinge. The case also includes a third portion hingedly coupled to the second portion. The case further includes a fourth portion hingedly coupled to the third portion. The fourth portion includes a hand support assembly at an inner surface of the fourth portion. The hand support assembly includes a perimeter frame, an inner frame, and a channel between the perimeter frame and the inner frame.

Various embodiments include a method for providing a case for an electrical device. The method includes providing a support assembly configured to be removably coupled to the electrical device. The method also includes providing a first portion coupled to at least a portion of the support assembly. The method further includes providing a second portion coupled to the first portion at a first hinge. The method also includes providing a third portion hingedly coupled to the second portion. The method further includes providing a fourth portion hingedly coupled to the third portion. The fourth portion includes a hand support assembly at an inner surface of the fourth portion. The hand support assembly includes a perimeter frame, an inner frame, and a channel between the perimeter frame and the inner frame.

In a number of embodiments, a case for an electrical device can include: (a) a first portion with a bottom surface; (b) a second portion adjacent to the first portion; (c) a third portion adjacent to the second portion; (d) a fourth portion adjacent to the third portion; and (e) a fifth portion with an interior surface and adjacent to the fourth portion. In this embodiment, at least one of the first portion or the third portion is configured to be removably coupled to the electrical device. Additionally, when the case is placed in an open configuration, the first portion is capable of being located over the fifth portion with the bottom surface of the first portion adjacent to the interior surface of the fifth portion.

In other embodiments, a holder for an electrical device can include: (a) an inner section with a bottom surface; (b) a first outer section adjacent to the inner section; (c) a second outer section with a first surface and adjacent to the first outer section; and (d) one or more ribs adjacent to the first surface of the second outer section. In these embodiments, the holder is configured to be removably coupled to the electrical device. Furthermore, the holder is configured to be placed in a position such that the inner section forming a substantially non-zero angle with the second outer section and the bottom surface of the inner section is at least partially supported by the first surface of the second outer section and one rib of the one or more ribs.

In yet another embodiment, a method of using a case with an electrical device includes: (a) providing the case to comprise: (1) a first portion with a bottom surface; (2) a second portion adjacent to the first portion; (3) a third portion adjacent to the second portion; (4) a fourth portion adjacent to the third portion; and (5) a fifth portion with an interior surface adjacent to the fourth portion; (b) coupling the electrical device to the case at the first portion; (c) placing the case in an open configuration with the bottom surface of the first portion over and adjacent to the interior surface of the fifth portion.

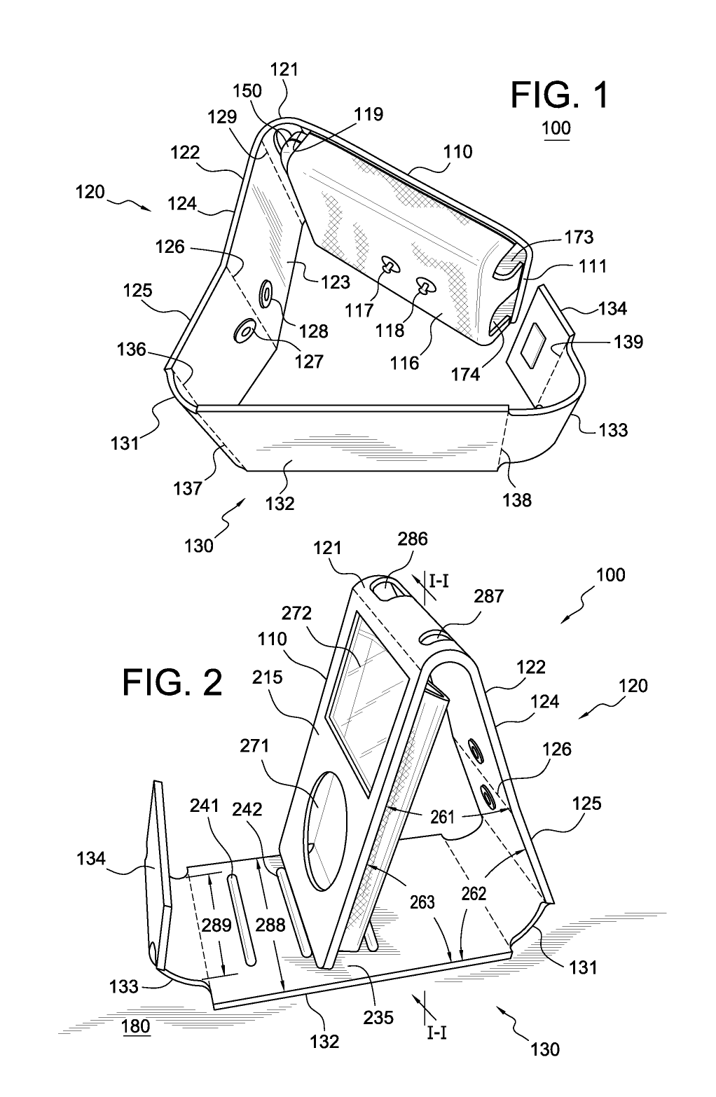

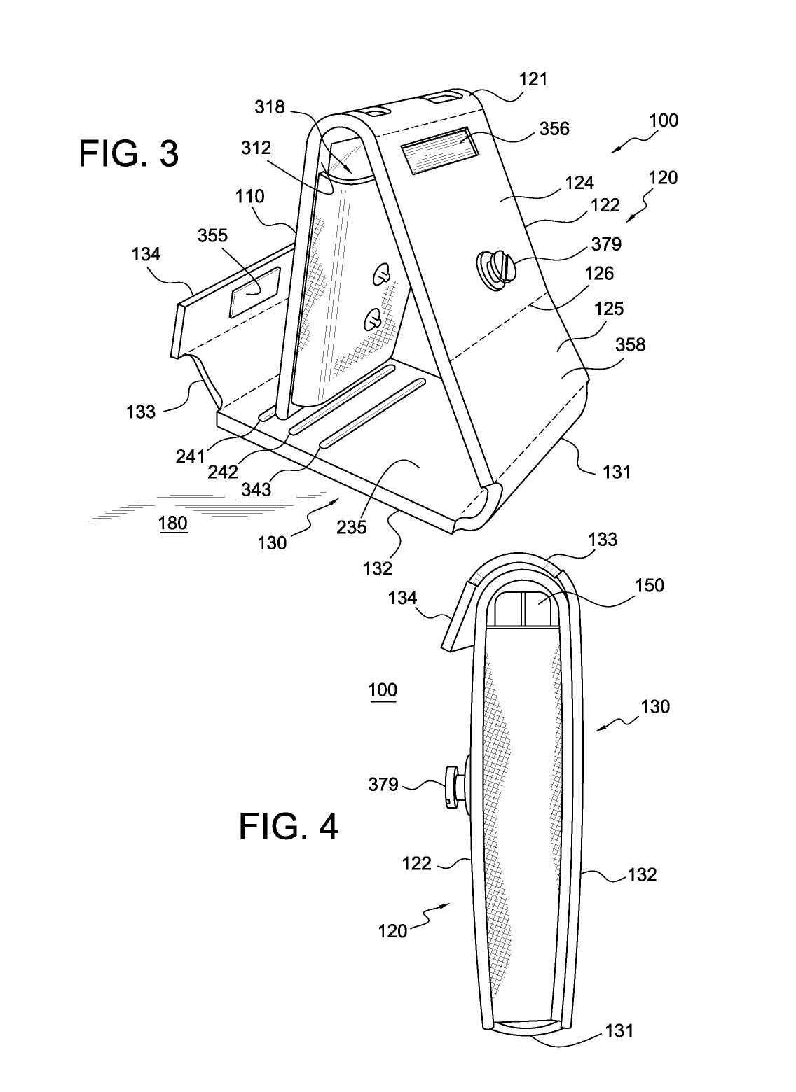

Turning to the drawings, FIG. 1 illustrates a bottom, side isometric view of a case 100 in a first embodiment of an open configuration and enclosing an electrical device 150, according to a first embodiment of case 100. FIG. 2 illustrates a top, front, side isometric view of case 100 in a second embodiment of an open configuration, according to the first embodiment of case 100. FIG. 3 illustrates top, back, side isometric view of case 100 in a third embodiment of the open configuration, according to the first embodiment of case 100. FIG. 4 illustrates a side view of case 100 in a closed configuration and enclosing electrical device 150, according to the first embodiment of case 100. Case 100 is merely exemplary and is not limited to the embodiments presented herein. Case 100 can be employed in many different embodiments or examples not specifically depicted or described herein.

In some embodiments, a holder or case 100 for electrical device 150 can include: (a) an inner portion 110 with a bottom surface 111; (b) an outer section 120 adjacent to inner portion 110; (c) an outer section 130 adjacent to outer section 120; and (d) one or more supports or ribs 241, 242, and 343 adjacent to outer section 130.

In some embodiments, case 100 can also include a connector 379 at an exterior surface 358 of outer section 120. As an example, connector 379 can be configured to couple to a clip (not shown) on a belt.

Case 100 is configured to be removably coupled to electrical device 150. In one example, inner portion 110 is configured to be coupled to electrical device 150. In alternative embodiments, outer section 120 is configured to be coupled to electrical device 150.

In one embodiment, outer section 120 can include: (a) a portion 121 adjacent to inner portion 110; and (b) a portion 122 adjacent to portion 121. Portion 122 can include an interior surface 123.

In various embodiments, at least a part of inner portion 110 can be contiguous with and/or continuous with at least a part of portion 121. Likewise, at least a part of portion 121 can be contiguous with and/or continuous with at least a part of portion 122. Furthermore, in some embodiments, inner portion 110 can be coupled to portion 121 at or by a hinge 119 with inner portion 110 and portion 121 configured to be folded along hinge 119. Likewise, portion 121 can be coupled to portion 122 at or by a hinge 129 with portions 121 and 122 configured to be folded along hinge 129.

In the same or a different embodiment, outer section 130 can include: (a) a portion 131 adjacent to portion 122; (b) a portion 132 with an interior surface 235 and adjacent to portion 131; (c) a portion 133 adjacent to portion 132; and (d) a portion 134 adjacent to portion 133. In one embodiment, ribs 241, 242, and 343 are adjacent to interior surface 235.

In many embodiments, at least a part of portion 131 can be contiguous with and/or continuous with at least a part of portion 122. Likewise, at least a part of portion 131 can be contiguous with and/or continuous with at least a part of portion 132. In the same or different embodiments, at least a part of portion 132 can be contiguous with and/or continuous with at least a part of portion 133. Additionally, in some embodiments, at least a part of portion 133 can be contiguous with and/or continuous with at least a part of portion 134.

In some examples, portion 122 can be coupled to portion 131 at or by a hinge 136 with portions 122 and 131 configured to be folded along hinge 136. Likewise, portion 131 can be coupled to portion 132 at or by a hinge 137 with portions 131 and 132 configured to be folded along hinge 137. In the same or different embodiments, portion 132 can be coupled to portion 133 at or by a hinge 138 with portions 132 and 133 configured to be folded along hinge 138. In some embodiments, portion 133 can be coupled to portion 134 at or by a hinge 139 with portions 133 and 134 configured to be folded along hinge 139. In some embodiments, hinges 119, 129, 136, 137, 138, and/or 139 are rows of stitching that extend across the width of case 100. In other embodiments, hinges 119, 129, 136, 137, 138, and/or 139 are fold lines or a region where two different materials are coupled together. In still other embodiments, case 100 does not include some of or any of hinges 119, 129, 136, 137, 138, or 139, and one or more of portions 121, 131, and 133 serve as the hinges.

In some embodiments, portion 132 can have a width 288, and portion 133 can have a width 289. In some examples, width 289 is less than width 288. For example, width 288 can be four to ten centimeters, and width 289 can be two to six centimeters. In a preferred example, width 288 is approximately six and a half centimeters, and width 289 is approximately five centimeters. Likewise, widths of portions 110, 121, 122, 131, 132, and 134 can be the same at four to ten centimeters. In a preferred example, widths of portions 110, 121, 122, and 132 are each also six and a half centimeters, and width of portion 131 is approximately five and a half centimeters.

In the same or different embodiments, width 289 is less than width 288, and portion 121 can have at least one aperture 287 to allow a user access to electrical device 150 when case 100 is in a closed configuration. Portion 121 can also allow the user access to electrical device 150 though aperture 287 and one or more apertures 286 when case 100 is in an open configuration.

Case 100 is configured to be placed in open or closed configurations. FIG. 1 illustrates case 100 in a first embodiment of the open configuration. FIGS. 2 and 3 illustrate case 100 in second and third embodiments of the open configuration on a flat surface 180, and FIG. 4 illustrates case 100 in the closed configuration. In the illustrated embodiments, when case 100 is in a closed configuration, outer section 130 wraps around inner portion 110 such that an exterior surface 215 of inner portion 110 contacts and/or is adjacent to interior surface 235.

In some embodiments, electrical device 150 includes: (a) a first side (not shown); (b) a second side (not shown) opposite the first side; and (c) a third side (not shown) adjacent to the first side and the second side. In various examples, the second side of electrical device 150 can include a video screen and/or a control mechanism. When case 100 is placed in a closed configuration and encases electrical device 150, portion 121 is adjacent to the third side of electrical device 150, portion 122 is adjacent to the first side of electrical device 150, and inner portion 110 is adjacent to the second side of electrical device 150.

In some examples, portion 134 can include a coupling mechanism 355, and portion 122 can include a coupling mechanism 356, as shown in FIG. 3. Coupling mechanism 355 can be designed to be coupled to coupling mechanism 356. In some embodiments, attaching coupling mechanisms 355 and 356 to each other secures case 100 in a closed configuration. In alternative embodiments, portion 133 includes a first coupling mechanism and portion 121 includes a second coupling mechanism. In this alternative embodiment, the first coupling mechanism is configured to be coupled to the second coupling mechanism to secure case 100 in a closed configuration.

In some embodiments, coupling mechanism 355 can include one or more connectors that can be coupled to one or more of complementary connectors forming coupling mechanism 356. In one embodiment, coupling mechanisms 355 and 356 are complementary Velcro® material. In other embodiments, coupling mechanisms 355 and 356 can be buttons, string ties, or the like. In some examples, coupling mechanisms 355 and 356 can also contain magnets to help align and couple coupling mechanisms 355 and 356.

In various embodiments, as shown in FIGS. 2 and 3, when case 100 is in the open configuration, the case is configured to be placed in a position such that bottom surface 111 is at least partially supported by interior surface 235 and at least one rib of ribs 241, 242, and 343. Moreover, in this configuration, inner portion 110 forms a non-zero angle 261 with portion 122; portion 122 forms a non-zero angle 262 with portion 132; and portion 132 forms a non-zero angle 263 with inner portion 110. In some embodiments, angles 261, 262, and 263 can be acute angles of a single triangle.

In one example, when bottom surface 111 is partially supported by rib 343, angle 261 can be approximately 30 degrees; angle 262 can be approximately 75 degrees; and angle 263 can be approximately 75 degrees. In the same or a different example, as shown in FIG. 2, when bottom surface 111 is partially supported by rib 242, angle 261 can be approximately 40 degrees; angle 262 can be approximately 70 degrees; and angle 263 can be approximately 70 degrees. Likewise, as shown in FIG. 3, when bottom surface 111 is partially supported by rib 241, angle 261 can be approximately 50 degrees; angle 262 can be approximately 65 degrees; and angle 263 can be approximately 65 degrees.

In other examples, angles 261, 262, and/or 263 are set such that inner portion 110 is at a comfortable viewing or operating position for a user of electrical device 150. In some embodiments, angles 261, 262, and/or 263 can be fixed to complement the features of electrical device 150. For example, if electrical device 150 is mostly used for viewing images or videos, angles 261, 262, and 263 can be different than if the user's interaction with electrical device 150 is mainly to change settings on a touch screen of electrical device 150.

In the same or different examples, portion 121 and portion 132 can provide support to inner portion 110 when case 100 is in the open configuration and inner portion 110 is located over portion 132 with bottom surface 111 adjacent to interior surface 235.

Referring again to FIGS. 1-4, inner portion 110 can include: (a) bottom surface 111; (b) an interior surface 312 adjacent to bottom surface 111; (c) exterior surface 215 adjacent to bottom surface 111 and opposite interior surface 312; and (d) a coupling mechanism 116 at interior surface 312. In some embodiments, when case 100 is placed in a closed configuration, exterior surface 215 is substantially parallel and/or adjacent to interior surface 235.

In some examples, interior surface 312 is configured to be removably coupled to electrical device 150. In one embodiment, interior surface 312 is removably coupled to electrical device 150 using coupling mechanism 116.

Coupling mechanism 116 can be configured to removably enclose electrical device 150. In some examples, coupling mechanism 116 can be a pocket. When coupling mechanism 116 is a pocket, electrical device 150 can be placed inside of coupling mechanism 116 through an opening 318 in coupling mechanism 116. In one embodiment, coupling mechanism 116 is a piece of material sewn or otherwise attached to three sides of interior surface 312. Opening 318 can be located at the unattached side of the material. In some examples, opening 318 is located opposite to bottom surface 111. In some examples, coupling mechanism 116 can include one or more apertures 173 and 174 to allow the user access to portions of electrical device 150. In one embodiment, apertures 173 and 174 allow the user to connect peripheral devices such as headphones or power supplies to electrical device 150 without removing electrical device 150 from case 100. In alternative embodiments, coupling mechanism 116 can be Velcro® material, strings ties, buttons, or the like.

Inner portion 110 can allow a user to view and use electrical device 150 when electrical device 150 is coupled to interior surface 312 and case 100 is in the open configuration. In one example, inner portion 110 can include one or more openings 271 and 272 to allow the user to view and use electrical device 150. In some examples, opening 272 can be covered by a clear material. The clear material can allow the user to view and/or touch a display or touch screen at the second side of electrical device 150, while protecting the screen from damage. In one example, the clear material is a clear plastic, for example, clear polyvinyl chloride (PVC).

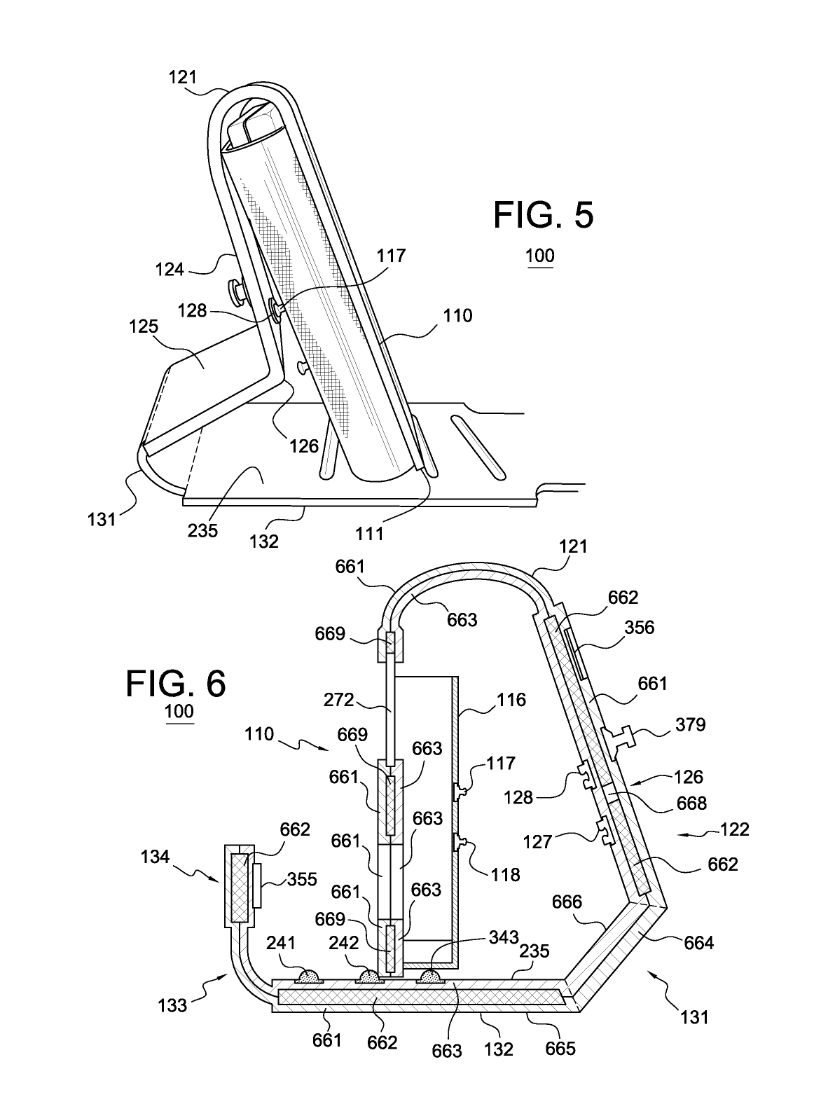

FIG. 5 illustrates a top, front, side isometric view of case 100 in a fourth embodiment of the open configuration, according to the first embodiment of case 100. As shown in FIGS. 1, 2, 3, and 5, portion 122 can include: (a) a segment 124 adjacent to portion 121; (b) a segment 125 adjacent to segment 124 and portion 131. In some examples, a bend region 126 separates and/or couples segment 124 from segment 125. Segment 124 is configured to be bent relative to segment 125 at bend region 126. In various examples, allowing segment 124 to be bent relative to segment 125 can increase the stability of case 100 when case 100 is in the open configuration and inner portion 110 is located over portion 132 with bottom surface 111 adjacent to interior surface 235.

In some embodiments, inner portion 110 can further include attachment mechanisms 117 and 118. In the same embodiment, portion 121 can include attachment mechanisms 127 and 128. Attachment mechanism 117 can include one or more connectors that can be coupled to one or more complementary connectors forming attachment mechanism 128. Likewise, attachment mechanism 118 can include one or more connectors that can be coupled to one or more complementary connectors forming attachment mechanism 127.

In one embodiment, attachment mechanisms 117 and 118 can be identical to or substantially similar to coupling mechanism 355. Moreover, attachment mechanisms 127 and 128 can be identical to or substantially similar to coupling mechanism 356.

In one example, attachment mechanisms 117 and 118 are adjacent to coupling mechanism 116. In the same or different embodiments, attachment mechanisms 127 and 128 are located at segments 125 and 124, respectively. In some examples, attachment mechanisms 117 and 118 can be male buttons, and attachment mechanisms 127 and 128 can be female buttons. In other embodiments, attachment mechanisms 117, 118, 127, and 128 are Velcro® material, strings ties, magnets, or the like.

Attachment mechanisms 117 and 118 can be coupled to attachment mechanisms 128 and 127, respectively, when case 100 is in a closed configuration. As shown in FIG. 5, attachment mechanism 117 can also be capable of being coupled to attachment mechanism 128 when case 100 is in open configuration and inner portion 110 is located over portion 132 with bottom surface 111 adjacent to interior surface 235. In some embodiments, segment 124 bends relative to segment 125 at bent region 126 when attachment mechanism 117 is coupled to attachment mechanism 128 and case 100 is in the open configuration with bottom surface 111 adjacent to interior surface 235. In alternative embodiments, attachment mechanisms 117 and 118 can both be coupled to attachment mechanisms 128 and 127, respectively, when case 100 is in the open configuration and inner portion 110 is located over portion 132 with bottom surface 111 adjacent to interior surface 235.

Referring back to FIGS. 2 and 3, interior surface 235 of portion 132 can include ribs 241, 242, and 343. In some examples, one or more of ribs 241, 242, and 343 extend in first direction and are substantially parallel to each other. In various embodiments, the first direction is substantially parallel to width 288 of interior surface 235 embodiments. In some examples, ribs 241, 242, and 343 extend approximately 70 to 90 percent of width 288 and have a thickness of two to four millimeters.

In various embodiments, rib 241 is separated from rib 242 by approximately ten to twenty millimeters. For example, rib 241 can be separated from rib 242 by fifteen millimeters. In the same or different examples, rib 242 can be separated from rib 343 by ten to twenty millimeters. In some embodiments, the distance between ribs 241, 242, and 343 is set based on the dimensions of electrical device 150. In some examples, the distances between adjacent ribs are the same. In other embodiments, the distance between adjacent ribs varies.

FIG. 6 illustrates a cross-sectional view along line I-I (FIG. 2) of case 100, according to the first embodiment of case 100. In the embodiment illustrated in FIG. 6, portion 132 can include: (a) an outer layer 661 with an exterior surface 665; (b) a stiffener layer 662 coupled to outer layer 661; (c) an inner layer 663 with interior surface 235 and coupled to stiffener layer 662.

In one embodiment, outer layer 661 and inner layer 663 can extend continuously through portions 133 and 134. However, in the embodiment illustrated in FIG. 6, portion 134 includes stiffener layer 662, but portion 133 does not include stiffener layer 662. In some examples, stiffener layer 662 is not present in portion 133 to allow easier folding of case 100 between the open and closed configurations.

In the embodiment illustrated in FIG. 6, portion 131 includes; (a) an inner layer 666; and (b) an outer layer 664. In some embodiments, inner layer 666 and outer layer 664 are made from different material than inner layer 663 and outer layer 661, respectively. In the same or a different embodiment, inner layer 666 and outer layer 664 are made from the same material. In alternative embodiments, portion 131 can include a stiffener layer. In the same or different examples, portion 131 can be made from the same material as coupling mechanism 116.

Portion 122 can include: (a) outer layer 661; (b) inner layer 663; and (c) stiffener layer 662 present throughout portion 122 except at bend region 126. In some embodiments, at bend region 126, a void region 668 exists between inner layer 663 and outer layer 661 to facilitate folding at bend region 126.

In the same or different embodiments, portion 121 can include: (a) outer layer 661; and (b) inner layer 663 coupled to outer layer 661. In alternative embodiments, portion 121 can include stiffener layer 662 between outer layer 661 and inner layer 663.

In inner portion 110, outer layer 661 and inner layer 663 can extend around the edges of openings 271 and 272. In some embodiments, inner portion 110 can include a stiffener layer 669. In many examples, stiffener layer 669 can be made from a different material than stiffener layer 662. For example, stiffener layer 662 can be composed of a material that provides more cushioning and protection than stiffener layer 669. In alternative embodiments, stiffener layers 662 and 669 can be made from the same material.

In an alternative example, portions 134, 132, 122, and/or 110 do not include a stiffener layer, or portions 110, 121, 122, 131, 132, 133, and 134 all include a stiffening layer. In yet another embodiment, inner portion 110, outer section 120, and/or outer section 130 are formed by a single layer (e.g., outer layer 661 or inner layer 663). In the same or different embodiments, coupling mechanism 116 can also include a stiffener layer.

Referring again to FIG. 6, outer layers 661 and 664 can be composed of a first material, and inner layers 663 and 666 can be composed of a second material. In some embodiments, outer layers 661 and 664 and inner layers 663 and 666 are made of leather (for example, split leather), suede, PVC, polyurethane, nylon, fabric, or the like. Stiffener layers 662 and 669 can be composed of cardboard, plastic, foam, or the like. In one example, stiffener layers 662 and 669 can include a layer of acrylonatrile butadiene styrene (ABS) and/or cardboard. In some embodiments, stiffener layers 662 and 669 lend rigidity and padding to case 100 to provide protection for electrical device 150 (FIGS. 1, 4, and 5).

In some examples, outer layer 661, stiffener layer 662, and inner layer 663 are stitched together. In other examples, some or all of outer layer 661, stiffener layer 662, and inner layer 663 can be attached together with an adhesive, for example, instead of or in addition to stitching.

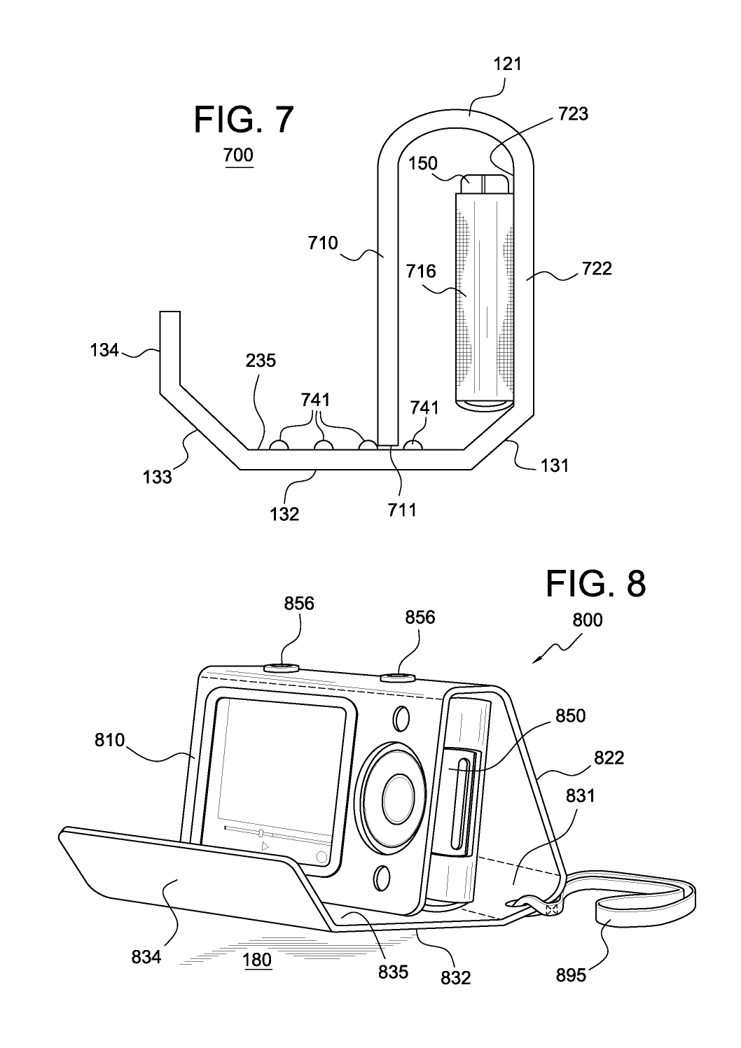

Turning to another embodiment, FIG. 7 illustrates a side view of a case 700 in an open configuration and enclosing electrical device 150, according to a second embodiment of case 100 (FIG. 1). Case 700 can include: (a) an inner portion 710 with a bottom surface 711; (b) an outer potion 722; (c) portions 121, 131, 132, 133, and 134; and (d) at least four ribs 741 at portion 132. When case 700 is placed in an open configuration, inner portion 710 is capable of being located over portion 132 with bottom surface 711 adjacent to interior surface 235.

In this embodiment, outer portion 722 is configured to be removably coupled to electrical device 150. In the example illustrated in FIG. 7, outer portion 722 can include a coupling mechanism 716 (e.g., a pocket) at an interior surface 723. In one example, coupling mechanism 716 can be identical to or substantially similar to coupling mechanism 116 (FIG. 1). In some embodiments, outer portion 722 can include openings (not shown) identical to or substantially similar to openings 271 and 272 (FIG. 2).

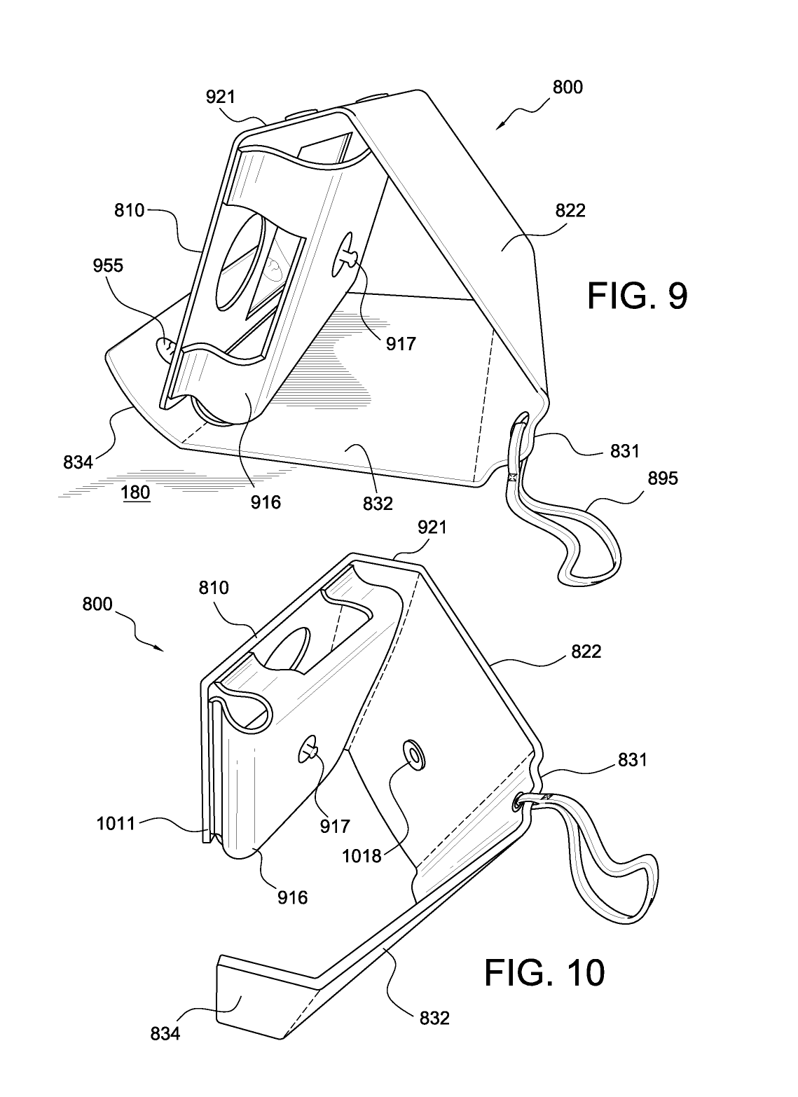

Turning to a further embodiment, FIG. 8 illustrates a top, front, side isometric view of a case 800 in a first embodiment of an open configuration and enclosing an electrical device 850, according to a third embodiment of case 100 (FIG. 1). FIG. 9 illustrates a top, back, side isometric view of case 800 in a second embodiment of the open configuration, according to the third embodiment of case 100 (FIG. 1). FIG. 10 illustrates a bottom, side isometric view of case 800 in a third embodiment of the open configuration, according to the third embodiment of case 100 (FIG. 1). In the embodiment illustrated in FIGS. 8-10, case 800 is configured to enclose electrical device 850. In some examples, electrical device 850 can have a different shape and/or size than electrical device 150 (FIGS. 1 and 5).

In some examples, case 800 can include: (a) an inner portion 810 with an coupling mechanism 916 and a bottom surface 1011; (b) a portion 921 adjacent to inner portion 810; (c) a portion 822 adjacent to portion 921; (d) a portion 831 adjacent to portion 822; (e) a portion 832 with an interior surface 835 and adjacent to portion 831; and (f) a portion 834 adjacent to portion 832. In some examples, case 800 does not include a portion similar to portion 133 (FIG. 1) and/or ribs 241, 242, and 343 (FIGS. 2 and 3) at portion 832. In alternative embodiments, case 800 can include portion 133 (FIG. 1) and/or ribs 241, 242, and/or 343 (FIGS. 2 and 3). When case 800 is placed in an open configuration, inner portion 810 is capable of being located over portion 832 with bottom surface 1011 adjacent to interior surface 835.

In some examples, coupling mechanism 916 can be identical to or substantially similar to coupling mechanism 116 (FIG. 1). In the same or different examples, an attachment mechanism 917 can be located at or adjacent to coupling mechanism 916. Portion 822 can include an attachment mechanism 1018 configured to be coupled to attachment mechanism 917. In some examples, portion 831 can include a coupling mechanism 895 configured to facilitate easy carrying of case 800 and electrical device 850 by a user.

Portion 834 can include a coupling mechanism 955, and a portion 921 can include a coupling mechanism 856. Coupling mechanism 955 can be configured to be coupled to coupling mechanism 856 to secure case 800 in the closed configuration. In some embodiments, attachment mechanisms 917 and 1018 can also be coupled to help hold case 800 in the closed configuration.

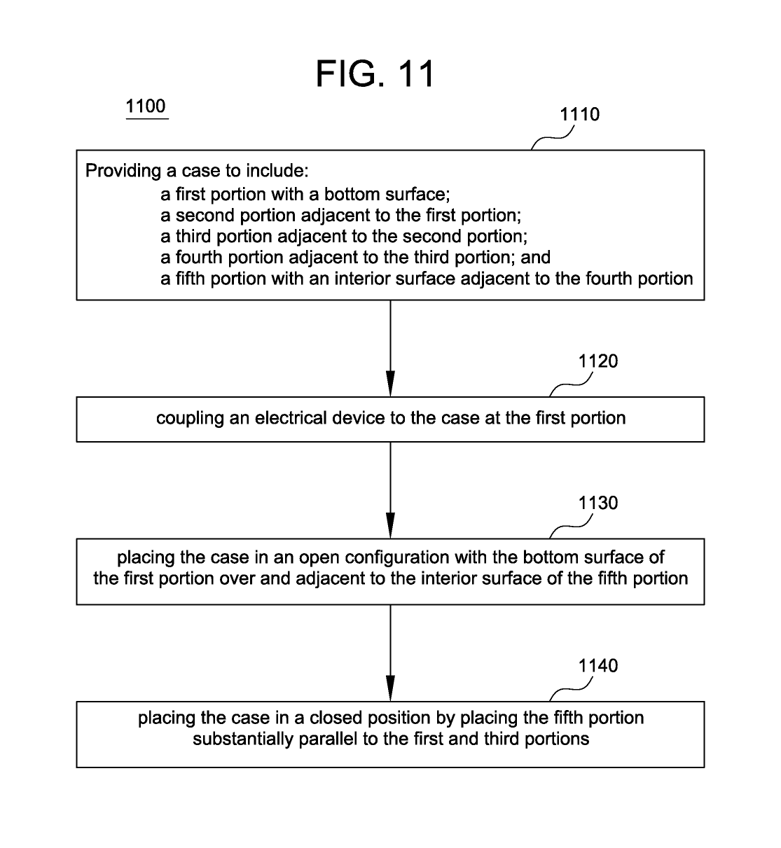

FIG. 11 illustrates a flow chart 1100 for an embodiment of a method of using a case with an electrical device. Flow chart 1100 includes a step 1110 of providing a case to include: (a) a first portion with a bottom surface; (b) a second portion adjacent to the first portion; (c) a third portion adjacent to the second portion; (d) a fourth portion adjacent to the third portion; and (e) a fifth portion with an interior surface and adjacent to the fourth portion. As an example, the case can be similar to cases 100, 700, or 800 of FIGS. 1, 7, and 8, respectively. In some embodiments, the first portion can be similar to inner portions 110, 710 or 810 of FIGS. 1, 7, and 8, respectively. Likewise, the second portion can be similar to portions 121 or 921 of FIGS. 1 and 9, respectively. The third portion can be similar to outer portions 122, 722, or 822 of FIGS. 1, 7, and 8, respectively. The fourth portion can be similar to portions 131 or 831 of FIGS. 1 and 8, respectively. The fifth portion can be similar to portions 132 or 832 of FIGS. 1 and 8, respectively. In the same or a different embodiment, the bottom surface can be similar to bottom surfaces 111, 711, or 1011 of FIGS. 1, 7, and 10, respectively, and the interior surface can be similar to interior surfaces 235, and 835 of FIGS. 2 and 8, respectively.

Flow chart 1100 in FIG. 11 continues with a step 1120 of coupling the electrical device to the case. As an example, the electrical device can be coupled to the case similar to the coupling of electrical devices 150 and 850 to portions 110 or 810 in FIGS. 1 and 8, respectively. In an alternative example, the electrical device can be coupled to the case similar to the coupling of electrical device 150 to outer portion 722 in FIG. 7. For example, the electrical device can be coupled to the case using an attachment mechanism similar to coupling mechanisms 116, 716, or 916 of FIGS. 1, 7, and 9, respectively.

Subsequently, flow chart 1100 includes a step 1130 of placing the case in an open configuration with the bottom surface of the first portion over and adjacent to the interior surface of the fifth portion. As an example, the case can be placed in an open configuration similar to the open configuration of case 100 in FIGS. 2, 3, and 5, case 700 in FIG. 7, and case 800 in FIGS. 8 and 9. In some embodiments, placing the bottom surface of the first portion over and adjacent to the interior surface of the fifth portion can be similar to the configuration of inner portion 110, portion 132, bottom surface 111, and interior surface 235 as shown in FIGS. 2, 3, and 5. In other embodiments, placing the bottom surface of the first portion over and adjacent to the interior surface of the fifth portion can be similar to the configuration of inner portion 710, portion 132, bottom surface 711 and interior surface 235 as shown in FIG. 7. In still further embodiments, placing the bottom surface of the first portion over and adjacent to the interior surface of the fifth portion can be similar to the configuration of inner portion 810, portion 832, bottom surface 1011, and interior surface 835 as shown in FIG. 8, 9, or 10.

In some embodiments, placing the case in the open configuration can also include removably attaching the first portion to the third portion. As an example, the first portion can be removably attached to the third portion similar to the coupling of inner portion 110 to portion 122 as shown in FIG. 5.

Next, flow chart 1100 includes a step 1140 of placing the case in a closed configuration by placing the fifth portion substantially parallel to the first and third portions. As an example, the case can be placed into the closed configuration similar to the closed portion of case 100 as shown in FIG. 4. In some examples, placing the fifth portion substantially parallel to the first and third portions can be similar to the placement of portion 132 substantially parallel to portions 110 and 122, as shown in FIG. 4.

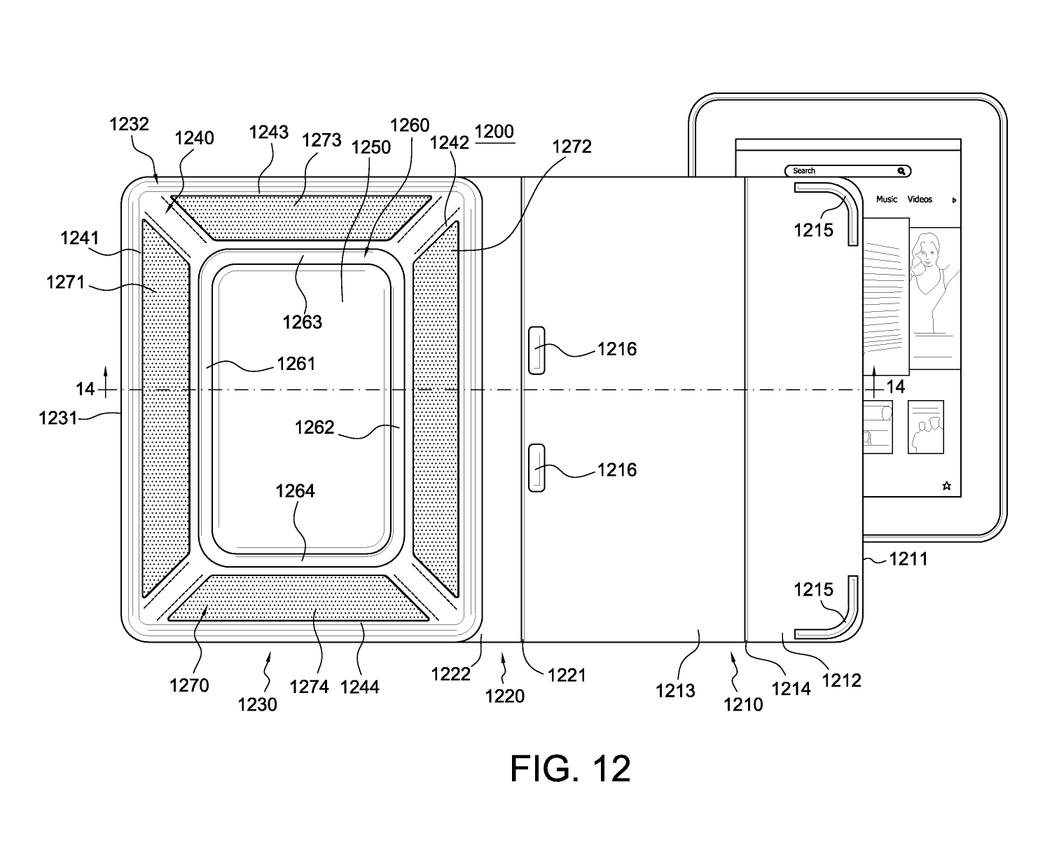

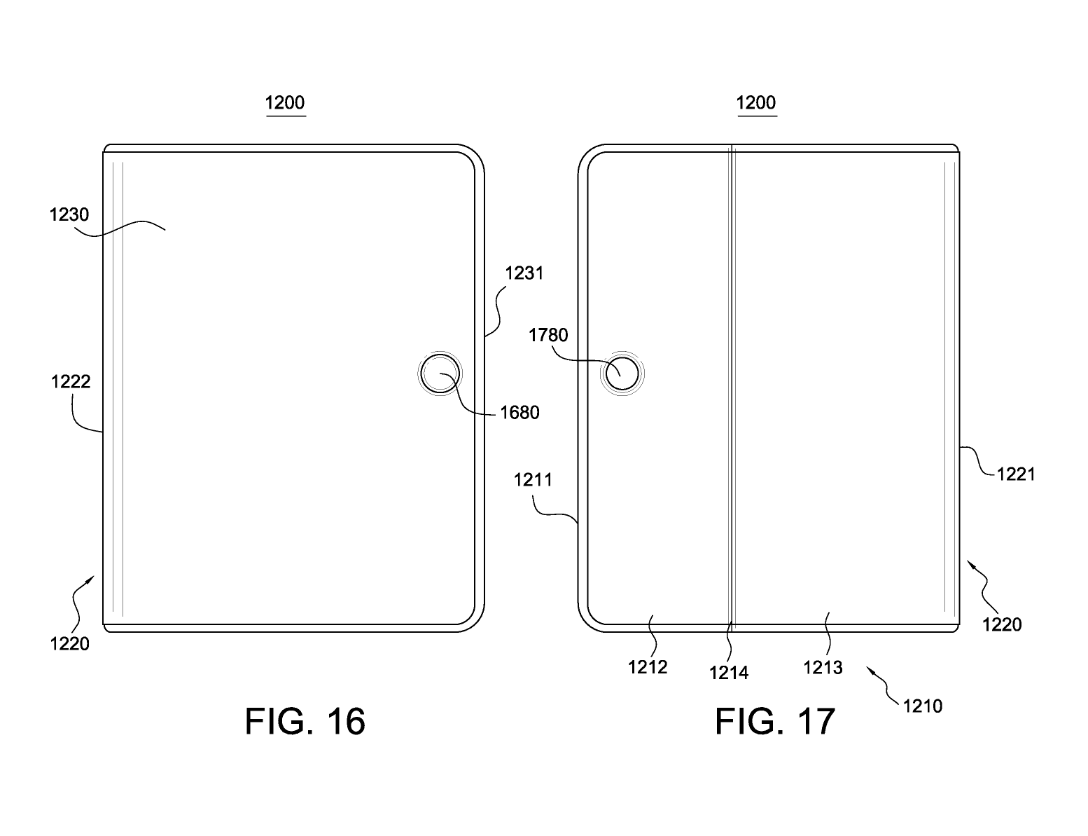

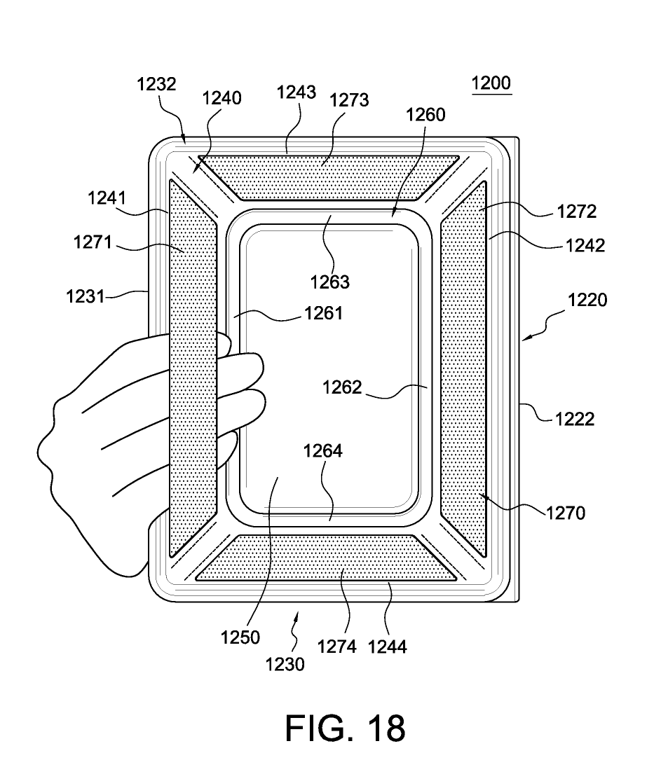

Turning ahead in the drawings, FIGS. 12-18 illustrate an example of a case for holding and securing an electronic device, such as a tablet computing device, such as an iPad, developed and sold by Apple, Inc., of Cupertino, Calif., or a Kindle Fire HD, developed and sold by Amazon.com, Inc., of Seattle, Wash. In the following paragraphs, the electronic device is described as a tablet computing device, but it should be understood that in some embodiments, a different electronic device can be held and/or secured within a case. Various embodiments of the case can be a handheld tablet case, which can be configured to hold and secure a tablet computing device or other electronic device. Embodiments of the handheld tablet case can be configured to allow the tablet computing device (a) to be opened in a viewing configuration at various viewing angles (as shown in FIG. 15, described below), (b) to be closed in a closed configuration (as shown in FIGS. 16-17, described below) in which the tablet computing device is secured inside the case, and/or (c) to be opened in a tablet configuration (as shown in FIG. 18, described below). Embodiments of the handheld tablet case can include a hand support assembly, which can include one or more hand straps and/or one or more channels or protrusions to allow a user to use the tablet computing device in a tablet configuration and to securely hold the handheld tablet case.

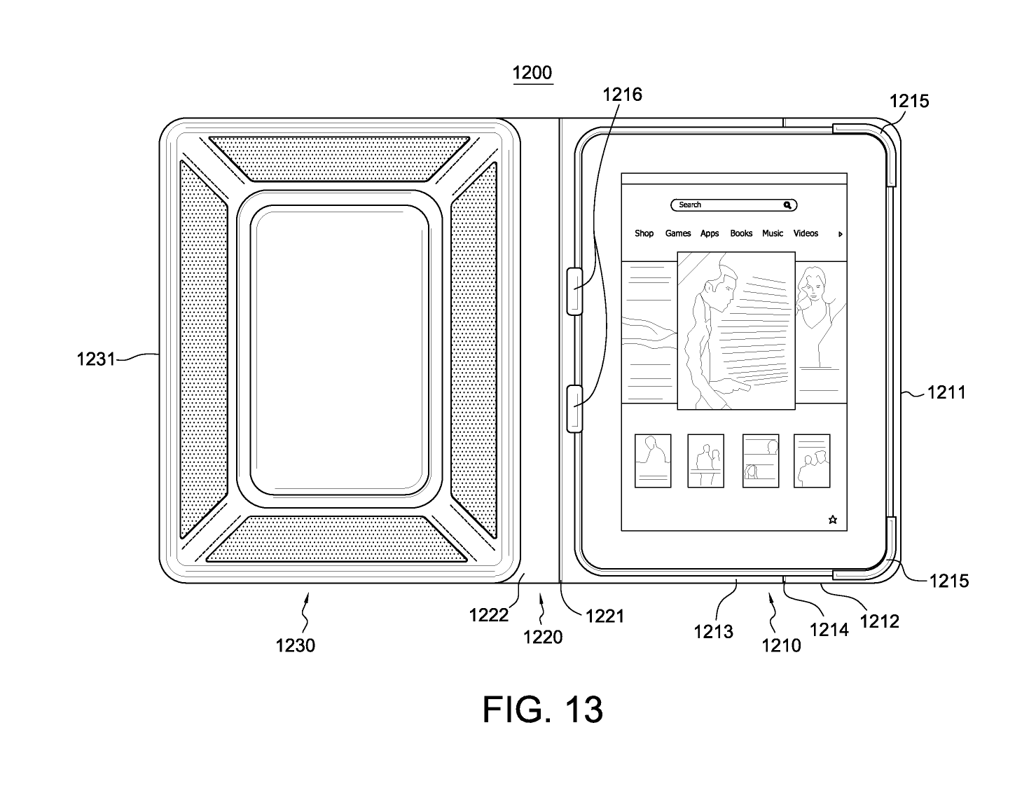

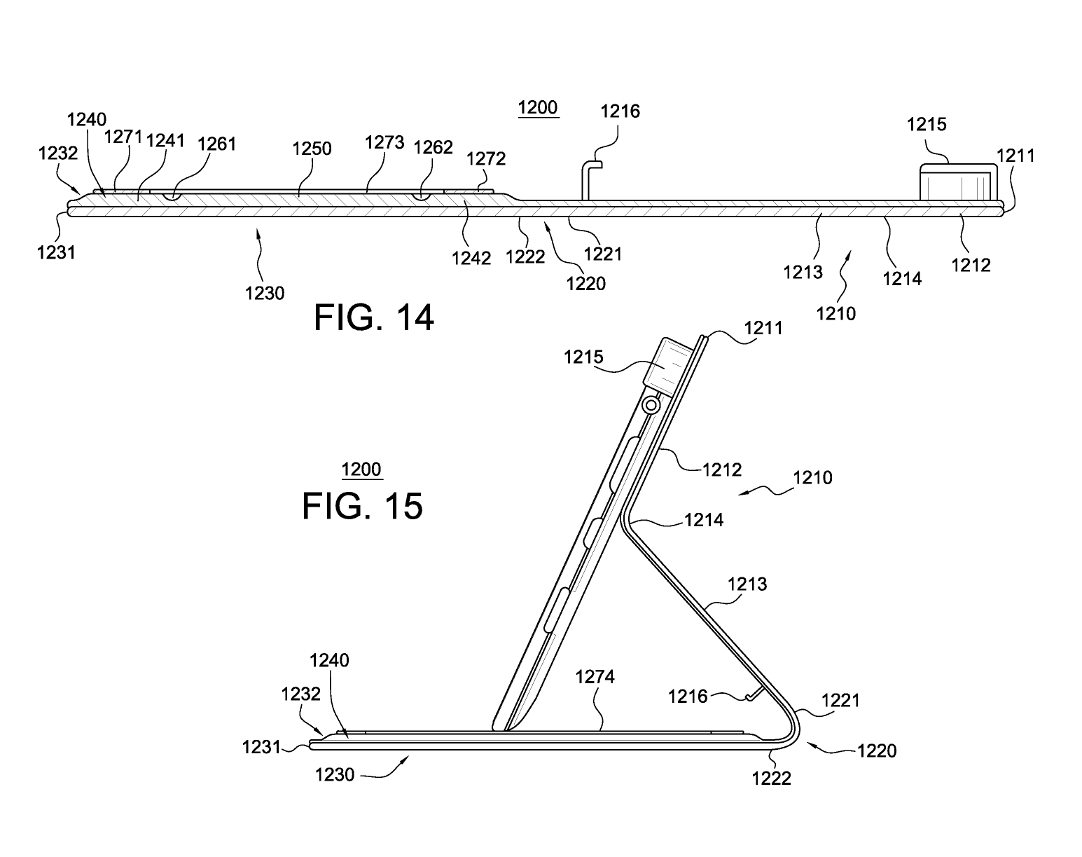

FIG. 12 illustrates a top view of a handheld tablet case 1200 in an open, unfolded configuration with a tablet computing device removed. FIG. 13 illustrates a top view of handheld tablet case 1200 in an open, unfolded configuration and holding the tablet computing device. FIG. 14 illustrates a cross-sectional, side elevational view of handheld tablet case 1200 in an open, unfolded configuration, where the cross-sectional view is taken along cross-sectional line 14-14 in FIG. 12. Handheld tablet case 1200 is merely exemplary and embodiments of the handheld tablet case are not limited to the embodiments presented herein. The handheld tablet case can be employed in many different embodiments or examples not specifically depicted or described herein. In many embodiments, handheld tablet case 1200 can include a back cover 1210, a front cover 1230, and/or a spine 1220 connecting back cover 1210 and front cover 1230. Back cover 1210 can have a dimension similar to a tablet computing device, and can extend, in certain embodiments, from a back edge 1211 to a back spine edge 1221, and from one side to the other side of handheld tablet case 1200. Front cover 1230 can have a dimension similar to back cover 1210 and can, in a number of embodiments, extend from a front edge 1231 to a front spine edge 1222 and from one side to the other side of handheld tablet case 1200. Spine 1220 can extend from front spine edge 1222 to back spine edge 1221 and from one side to the other side of handheld tablet case 1200. Spine 1220 can have a dimension from front spine edge 1222 to back spine edge 1221 sufficient to allow handheld tablet case 1200 to close in a closed configuration, as shown in FIGS. 16-17, described below.

In various embodiments, back cover 1210 can include a first back region 1212 and a second back region 1213. First back region 1212 can be adjacent to back edge 1211 and can extend from back edge 1211 to a back cover hinge 1214. Second back region 1213 can be adjacent to back cover hinge 1214 and can extend between back cover hinge 1214 and back spine edge 1221. The component parts of handheld tablet case 1200, such as front cover 1230, spine 1220, second back region 1213, and/or first back region 1212 can be made of leather (for example, split leather), suede, PVC, polypropylene, polyethylene, nylon, fabric, or another such suitable material. In some embodiments, the parts can include two or more layers of the same or different materials. One or more of the parts can include stiffener layers between the layers to provide additional structural support. Stiffener layers can be made of a suitable rigid or semi-rigid material, such as cardboard, acrylonitrile butadiene styrene (ABS), plastic, foam, or another such suitable material. In certain embodiments, the layers can be stitched together or attached together with an adhesive. For example, front cover 1230, second back region 1213, and first back region 1212 can include stiffener layers, while spine 1220 and back cover hinge 1214 do not include stiffener layers, so as to allow handheld tablet case 1200 to fold flexibly at such regions. In other embodiments, one or more component parts of handheld tablet case 1200 can be made of a suitable rigid polymer (e.g., polycarbonate (PC), ABS, metal (e.g., aluminum), ceramic material, thermoplastic elastomer (TPE) (e.g., thermoplastic polyurethane (TPU)), and/or semi-rigid polymer.

In some embodiments, a support assembly can be attached to an inner side of back cover 1210 and/or first back region 1212, and/or vise versa. As an example, the support assembly can include one or more first tablet supports 1215 and/or one or more second tablet supports 1216, which can be configured to support and fittingly secure a tablet computing device. As an example, first back region 1212 can include two first tablet supports 1215 positioned adjacent to back edge 1211 and each adjacent to an opposite side of handheld tablet case 1200. First tablet supports 1215 can include a lip to hold a side or edge of the tablet computing device. As a further example, second back region 1213 can include two second tablet supports 1216 positioned adjacent to back spine edge 1221. Second tablet supports 1216 can include a lip to hold a side or edge of the tablet computing device. In some embodiments, second tablet supports 1216 can be configured to fittingly secure the tablet computing device (as shown in FIG. 13), and to allow a user to exert a sufficient force on second tablet supports 1216 toward back spine edge 1221, such as to allow the tablet computing device to be released and removed from handheld tablet case 1200 (as shown in FIG. 12). In certain embodiments, first tablet supports 1215 and/or second tablet supports 1216 can be made of a suitable rigid polymer (e.g., polycarbonate (PC) or ABS), metal (e.g., aluminum), or ceramic material. In other embodiments, first back region 1212 can be connected to another suitable support assembly that is configured to hold and fittingly secure the tablet computing device. As an example, the support assembly can include a pocket or an X-frame. In a number of embodiments, the support assembly can include a back cover, one or more sides, and a front perimeter frame to hold and support the tablet computing device. As another example, an X-frame can be made of rigid plastic.

In various embodiments, front cover 1230 can include on its inner side a hand support assembly 1232. Hand support assembly 1232 can include a perimeter frame 1240, an inner frame 1250, and/or a channel 1260 between perimeter frame 1240 and inner frame 1250. In certain embodiments, perimeter frame 1240 can include a perimeter front edge portion 1241 extending from front edge 1231 to a channel front edge portion 1261, a perimeter spine edge portion 1242 extending from front spine edge 1222 to a channel spine edge portion 1262, a perimeter first side portion 1243 extending from a first side of front cover 1230 to a channel first side portion 1263, and/or a perimeter second side portion 1244 extending from a second side of front cover 1230 to a channel second side portion 1264. The portions of perimeter frame 1240 (e.g., 1241, 1242, 1243, 1244) can each be substantially co-planar and can have a substantially similar width from the respective sides of front cover 1230 to the respective portions of channel 1260 (e.g., 1261, 1262, 1263, 1264). In a number of embodiments, the portions of perimeter frame 1240 (e.g., 1241, 1242, 1243, 1244) can have a thickness greater than the respective portions of channel 1260 (e.g., 1261, 1262, 1263, 1264), as shown in FIG. 14. In a number of embodiments, inner frame 1250 can be substantially co-planar with perimeter frame 1240. In certain embodiments, the portions of channel 1260 (e.g., 1261, 1262, 1263, 1264) can be rounded recesses, which can provide a slot to allow a user's fingers to be inserted, which can advantageously allow the user to securely hold handheld tablet case 1200 when handheld tablet case 1200 is in a tablet configuration (as shown in FIG. 18, described below).

In other embodiments, channel 1260 and inner frame 1250 can both be co-planar and recessed with respect to perimeter frame 1240. Perimeter frame 1240 can allow a user's fingers to wrap around a portion of perimeter frame 1240 (e.g., 1241, 1242, 1243, 1244), rest on the recessed surfaces of channel 1260 and/or inner frame 1250, which can advantageously allow the user to securely hold handheld tablet case 1200 when handheld tablet case 1200 is in a tablet configuration (as shown in FIG. 18, described below). In yet additional embodiments, channel 1260 can protrude with respect to perimeter frame 1240 and inner frame 1250, and can have a greater thickness than inner frame 1250 and the portions of perimeter frame 1240 (e.g., 1241, 1242, 1243, 1244). In such embodiments, inner frame 1250 and perimeter frame 1240 can be co-planar with each other, and a user's fingers can wrap around the protrusion of channel 1260 to securely hold handheld tablet case 1200 when handheld tablet case 1200 is in a tablet configuration (as shown in FIG. 18, described below). Hand support assembly 1232 can be made of a suitable rigid polymer (e.g., PC or ABS), metal (e.g., aluminum), or ceramic material, and in some embodiments can be molded or formed as a single piece.

In many embodiments, the perimeter frame 1240 can include one or more hand straps 1270. For example, perimeter front edge portion 1241 can include a front edge hand strap 1271, perimeter spine edge portion 1242 can include a spine edge hand strap 1272, perimeter first side portion 1243 can include a first side hand strap 1273, and perimeter second side portion 1244 can include a second side hand strap 1274. In certain embodiments, each of hand straps 1270 (e.g., 1271, 1272, 1273, 1274) can have a width equal to or less than the width of the respective portion of perimeter frame 1240 (e.g., 1241, 1242, 1242, 1244). In a number of embodiments, each of hand straps 1270 (e.g., 1271, 1272, 1273, 1274) can rest across the respective portions of perimeter frame 1240 (e.g., 1241, 1242, 1243, 1244) and can be attached diagonally proximate to the respective interfaces between the portions of perimeter frame 1240 (e.g., 1241, 1242, 1243, 1244), such that the longitudinal portion of the hand strap proximate to the side or edge of front cover 1230 is longer than the longitudinal portion of the hand strap proximate to the respective portion of channel 1260 (e.g., 1261, 1262, 1263, 1264). For example, front edge hand strap 1271 can extend longitudinally along perimeter front edge portion 1241, and can be longer at the portion proximate to front edge 1231 than at the portion proximate to channel front edge portion 1261. One or more of the hand straps (e.g., 1271, 1272, 1273, 1274) can be made of an elastic ribbon, which can be made of synthetic or natural rubber and a fabric. In various embodiments, one or more of hand straps 1270 (e.g., 1271, 1272, 1273, 1274) can include soft and/or padded fabric, or another material suitable for extended contact with a hand. A user can employ one or more of hand straps 1270 (e.g., 1271, 1272, 1273, 1274) by placing the user's fingers between the hand strap and the respective portion of the perimeter frame (e.g., 1241, 1242, 1243, 1244), which can advantageously provide additional support to secure handheld tablet case 1200 in the user's hands when handheld tablet case 1200 is used in a tablet configuration (as shown in FIG. 18, described below).

FIG. 15 illustrates a side elevational view of handheld tablet case 1200 in a viewing configuration with a tablet computing device. In various embodiments in a viewing configuration, front cover 1230 can provide a support base for handheld tablet case 1200, and handheld tablet case 1200 can hold the tablet computing device in a partially upright angled position, thus allowing the user to manipulate a touchscreen of the tablet computing device. In a number of embodiments, back cover 1210 can fold axially around back cover hinge 1214 such that first back region 1212 can be positioned at various different angles with respect to second back region 1213. Additionally, in various embodiments, hinge 1220 can provide an axial hinge for second back region 1213, allowing second back region 1213 to adjust to various angles with respect to front cover 1230. Together, these hinges can allow the tablet computing device to be adjusted to various viewing angles, such that one of the longer edges of the tablet computing device can be held by first tablet supports 1215, and the opposite longer edge of the tablet computing device can rest upon the inner surface of front cover 1230. In such configurations, second tablet supports 1216 can be detached from the tablet computing device. In other embodiments, as described above, the tablet computing device can be held by a another suitable support assembly.

First back region 1212 can provide a back support for the tablet computing device and/or the support assembly and can be substantially parallel to the back plane of the tablet computing device. Second back region 1213 can prop up first back region 1212 and the tablet computing device. In some viewing configurations, in various embodiments, first back region 1212 can form a substantially right angle with second back region 1213. In other viewing configurations, the tablet computing device can be positioned at a more upright viewing position, such that first back region 1212 forms an obtuse angle with second back region 1213 at back cover hinge 1214. In other viewing configurations, the tablet computing device can be positioned at a less upright viewing position, such that first back region 1212 forms an acute angle with second back region 1213 at back cover hinge 1214. The viewing angle of the tablet computing device can be adjusted to provide a comfortable viewing or operating position for a user of the tablet computing device. When in a viewing configuration, handheld tablet case 1200 can thus allow a user to view the tablet computing device screen at various viewing angles.

In certain embodiments, the tablet computing device and/or the support assembly can rest upon one or more of the hand straps, such as first side hand strap 1273 and/or second side hand strap 1274. The top side of one or more of the hand straps can, in certain embodiments, include a high friction material to improve the stability of handheld tablet case 1200 in a viewing configuration and to prevent the tablet computing device from slipping. In certain other embodiments, the tablet computing device and/or the support assembly can rest upon inner frame 1250 and/or the protrusion of channel 1260. In such embodiments, inner frame 1250 and/or portions of channel 1260, such as channel first side portion 1263 and/or channel second side portion 1264 can include a high friction material to improve stability and prevent the tablet computing device from slipping.

FIG. 16 illustrates a top view of handheld tablet case 1200 in a closed configuration, showing the outer side of front cover 1230. FIG. 17 illustrates a bottom view of handheld tablet case 1200 in a closed configuration, showing the outer side of back cover 1210. In various embodiments in a closed configuration, the surfaces of the components of hand support assembly 1232 can rest against and/or be positioned in close proximity to and substantially parallel to the tablet computing device and/or the support assembly for the tablet computing device. In a closed configuration, in some embodiments, front edge 1231 (FIG. 16) can rest against or be positioned in close proximity to back edge 1211 (FIG. 17). As shown in FIG. 17, first back region 1212 can be substantially co-planar with second back region 1213, and back cover 1210 can be substantially parallel with front cover 1230 (FIG. 16). In some embodiments in the closed configuration, front edge 1231 (FIG. 16) can include a magnet that can magnetically couple to a magnet in back edge 1211 (FIG. 17). In other embodiments, handheld tablet case 1200 can include other suitable forms of connectors, such as flaps, protrusions, recesses, snaps, hook-and-loop tape, etc. to secure handheld tablet case 1200 in a closed configuration.

In a number of embodiments, when handheld tablet case 1200 is in a closed configuration, it can securely hold and partially or fully surround the tablet computing device. A closed configuration can, in various embodiments, provide protection for the tablet computing device and its screen from damage. In some embodiments, front cover 1230 can include a front alignment aid 1680 (FIG. 16) and back cover 1210 can include a back alignment aid 1780 (FIG. 17). In certain embodiments, front alignment aid 1680 (FIG. 16) can protrude with respect to the outer side of front cover 1230, and back alignment aid 1780 (FIG. 17) can be recessed with respect to the outer side of back cover 1210. Front alignment aid 1680 (FIG. 16) and back alignment aid 1780 (FIG. 17) can assist a user in aligning handheld tablet case 1200 in a tablet configuration (as shown in FIG. 18, described below).

FIG. 18 illustrates a bottom view of handheld tablet case in a tablet configuration, showing the inner side of front cover 1230. In a tablet configuration, handheld tablet case 1230 can be folded axially around hinge 1220 such that the outer face of front cover 1230 (as shown in FIG. 16) can rest against and be substantially parallel with the outer face of back cover 1210 (as shown in FIG. 17). In a tablet configuration, in some embodiments, front edge 1231 can rest against or be positioned in close proximity to back edge 1211 (FIGS. 12 and 17). In some embodiments, front alignment aid 1680 (FIG. 16) and back alignment aid 1780 (FIG. 17) can align and engage, to allow a user to align front cover 1230 with back cover 1210 and to prevent slippage of back cover 1210 with respect to front cover 1230. Front alignment aid 1680 (FIG. 16) and back alignment aid 1780 (FIG. 17) can comprise magnets or a magnet and a piece of metal. Alternatively, or in addition, front alignment aid 1680 (FIG. 16) and back alignment aid 1780 (FIG. 17) can be include or be replaced with other suitable forms of connectors, such as flaps, protrusions, recesses, snaps, hook-and-loop tape, etc. to secure handheld tablet case 1200 in a tablet configuration.

In a tablet configuration, in certain embodiments, the touchscreen of the tablet computing device can be uncovered and accessible for user manipulation. The user can place one or both hands on the bottom of handheld tablet case 1200 on hand support assembly 1232. For example, the user can place fingers of one hand between front edge hand strap 1271 and front edge portion 1241 and place the fingertips in channel front edge portion 1261, so as to more securely hold the tablet computing device when using the other hand to manipulate the touchscreen. Many tablet computing devices support use in both a landscape and a portrait orientation, and many tablet computing devices support a user rotating the device in any orientation. Advantageously, handheld tablet computing 1200 can include hand straps 1270 (e.g., 1271, 1272, 1273, 1274), portions of perimeter frame 1240 (e.g., 1241, 1242, 1243, 1244), and/or portions of channel 1260 (e.g., 1261, 1262, 1263, 1264) on each of the four sides of front cover 1230, which can allow the user, for example, to use the same hand (such as the non-dominant hand) with hand support assembly 1232 in any orientation of the tablet computing device while using the other hand to manipulate the touchscreen of the tablet computing device. Additionally, a user may place both hands in the same or different portions of hand support assembly 1232, for example, through hand straps on opposite sides of front cover 1230 (e.g., 1271 and 1272), such as when holding the tablet computing device in handheld tablet case 1200 to watch a movie.

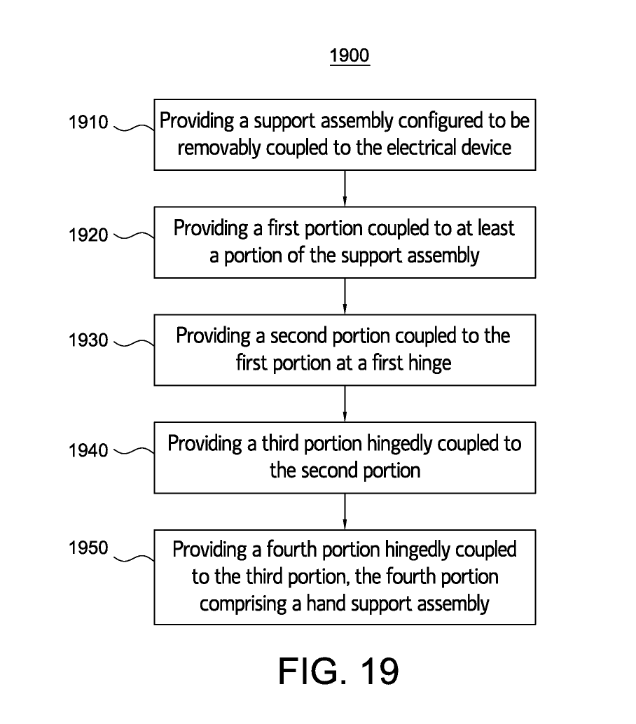

Turning ahead in the drawings, FIG. 19 illustrates a flow chart for an embodiment of method 1900 for providing a case for an electrical device. Method 1900 is merely exemplary and is not limited to the embodiments presented herein. Method 1900 can be employed in many different embodiments or examples not specifically depicted or described herein. In some embodiments, the procedures, the processes, and/or the activities of method 1900 can be performed in the order presented. In other embodiments, the procedures, the processes, and/or the activities of the method 1900 can be performed in any other suitable order. In still other embodiments, one or more of the procedures, the processes, and/or the activities in method 1900 can be combined or skipped.

Referring to FIG. 19, method 1900 can include a block 1910 of providing a support assembly. In many embodiments, the support assembly can be similar or identical to first tablet supports 1215 (FIG. 12) and/or second tablet supports 1216 (FIG. 12). In other embodiments, the support assembly can be a pocket or an X-frame. The many embodiments, the support assembly can be configured to be removably coupled to the electrical device.

Method 1900 also can include a block 1920 of providing a first portion. In many embodiments, the first portion can be similar or identical to first back region 1212 (FIG. 12). In many embodiments, the first portion can be coupled to at least a portion of the support assembly. For example, first back region 1212 (FIG. 12) can be coupled to first tablet supports 1215 (FIG. 12).

Method 1900 also can include a block 1930 of providing a second portion. In many embodiments, the second portion can be similar or identical to second back region 1213 (FIG. 12). In various embodiments, the second portion can be coupled to at least a portion of the support assembly. In several embodiments, the second portion can be coupled to the first portion at a first hinge. In a number of embodiments, the first hinge can be similar or identical to back cover hinge 1214 (FIG. 12). For example, second back region 1213 (FIG. 12) can be coupled to first back region 1212 (FIG. 12) at back cover hinge 1214 (FIG. 12).

Method 1900 also can include a block 1940 of providing a third portion. In many embodiments, the third portion can be similar or identical to spine 1220 (FIG. 12). In several embodiments, the third portion can be hingedly coupled to the second portion. For example, spine 1220 (FIG. 12) can be hingedly coupled to second back region 1213 (FIG. 12) at back spine edge 1221 (FIG. 12).

Method 1900 also can include a block 1950 of providing a fourth portion. In many embodiments, the fourth portion can be similar or identical to front cover 1230 (FIG. 12). In several embodiments, the fourth portion can be hingedly coupled to the third portion. For example, front cover 1230 (FIG. 12) can be hingedly coupled to spine 1220 (FIG. 12) at front spine edge 1222 (FIG. 12). In a number of embodiments, the fourth portion can include a hand support assembly. The hand support assembly can be similar or identical to hand support assembly 1232 (FIG. 12). In many embodiments, the hand support assembly can be located at an inner surface of the fourth portion. In various embodiments, the hand support assembly can include a perimeter frame, an inner frame, and/or a channel between the perimeter frame and the inner frame. The perimeter frame can be similar or identical to perimeter frame 1240 (FIG. 12), the inner frame can be similar or identical to inner frame 1250 (FIG. 12), and/or the channel can be similar or identical to channel 1260.

Although the invention has been described with reference to specific embodiments, it will be understood by those skilled in the art that various changes may be made without departing from the spirit or scope of the invention. For example, to one of ordinary skill in the art, it will be readily apparent portion 133 (FIG. 1) and portion 121 (FIG. 1) can include other complementary coupling mechanisms in addition to or instead of coupling mechanisms 355 (FIG. 3) and 356 (FIG. 3). Additional examples of such changes have been given in the foregoing description. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that various elements of FIGS. 1-19 may be modified, and that the foregoing discussion of certain of these embodiments does not necessarily represent a complete description of all possible embodiments. Rather, the detailed description of the drawings, and the drawings themselves, disclose at least one preferred embodiment of the invention, and may disclose alternative embodiments of the invention.

All elements claimed in any particular claim are essential to the invention claimed in that particular claim. Consequently, replacement of one or more claimed elements constitutes reconstruction and not repair. Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A case for an electrical device, the case comprising:
a support assembly configured to be removably coupled to the electrical device;
a first portion coupled to at least a portion of the support assembly;
a second portion coupled to the first portion at a first hinge;
a third portion hingedly coupled to the second portion; and
a fourth portion hingedly coupled to the third portion, the fourth portion comprising a hand support assembly at an inner surface of the fourth portion,
wherein:
the hand support assembly comprises a perimeter frame, an inner frame, and a channel between the perimeter frame and the inner frame.

2. The case of claim 1, wherein:
a thickness of at least a portion of the perimeter frame is greater than a thickness of at least a portion of the channel.

3. The case of claim 1, wherein:
the inner frame is substantially co-planar with the perimeter frame.

4. The case of claim 1, wherein:
the channel is substantially co-planar with the inner frame; and
a thickness of at least a portion of the perimeter portion is greater than a thickness of at least of portion of the channel and is greater than a thickness of at least a portion of the inner frame.

5. The case of claim 1, wherein:
the inner frame is substantially co-planar with the perimeter frame; and
a thickness of at least a portion of the channel is greater than a thickness of at least a portion of the perimeter frame and is greater than at least a portion of the inner frame.

6. The case of claim 1, wherein:
the perimeter frame comprises one or more hand straps.

7. The case of claim 1, wherein:
the hand support assembly comprises four sides; and
the perimeter frame comprises four portions each extending between the channel and a different one of the four sides of the hand support assembly.

8. The case of claim 7, wherein:
each of the four portions of the perimeter frame is substantially co-planar and has a substantially identical width.

9. The case of claim 7, wherein:
each of the four portions of the perimeter frame comprise a hand strap.

10. The case of claim 9, wherein:
each of the hand straps has a substantially identical width.

11. The case of claim 9, wherein, for each hand strap:
a first portion of the hand strap is located closer to the channel than a second portion of the hand strap; and
the second portion of the hand strap is longer than the first portion of the hand strap.

12. The case of claim 1, wherein:
the first portion is configured to be substantially parallel to the electrical device when the support assembly is coupled to the electrical device.

13. The case of claim 1, wherein:
the support assembly, the first portion, the second portion, the third portion, and the fourth portion are configured such that an outer surface of the first portion and an outer surface of the second portion are substantially parallel with and adjacent to an outer surface of the fourth portion when the case is in a tablet configuration; and
the support assembly, the first portion, the second portion, the third portion, and the fourth portion are configured such that, when the case is in the tablet configuration and the electrical device is coupled to the support assembly, a screen of the electrical device is uncovered on a first side of the case, and the hand support assembly is uncovered on a second side of the case opposite the first side of the case.

14. The case of claim 14, wherein:
an outer surface of the first portion includes a first alignment aid;
an outer surface of the fourth portion includes a second alignment aid; and
the first alignment aid and the second alignment aid are configured such that the first alignment aid engages with the second alignment aid when the case is in the tablet configuration.

15. The case of claim 15, wherein:
the first alignment aid and the second alignment aid each comprise a magnet configured to magnetically couple the first alignment aid to the second alignment aid when the case is in the tablet configuration.

16. The case of claim 1, wherein:
the support assembly, the first portion, the second portion, the third portion, and the fourth portion are configured such that the hand support assembly is substantially parallel with and adjacent to the electrical device when the support assembly is coupled to the electrical device and the case is in a closed configuration.

17. The case of claim 1, wherein:
the support assembly, the first portion, the second portion, the third portion, and the fourth portion are configured such that a first portion of the electrical device can be located over and adjacent to the hand support assembly when the case is in a viewing configuration; and
the case is configured such that the electrical device can be placed at two or more viewing angles when the case is in a viewing configuration.

18. A method for providing a case for an electrical device, the method comprising:
providing a support assembly configured to be removably coupled to the electrical device;
providing a first portion coupled to at least a portion of the support assembly;
providing a second portion coupled to the first portion at a first hinge;
providing a third portion hingedly coupled to the second portion; and
providing a fourth portion hingedly coupled to the third portion, the fourth portion comprising a hand support assembly at an inner surface of the fourth portion,
wherein:
the hand support assembly comprises a perimeter frame, an inner frame, and a channel between the perimeter frame and the inner frame.

19. The method of claim 18, wherein:
the inner frame is substantially co-planar with the perimeter frame; and
a thickness of at least a portion of the perimeter frame and a thickness of at least a portion of the inner frame are each greater than a thickness of at least a portion of the channel.

20. The method of claim 18, wherein:
the perimeter frame comprises one or more hand straps.
